(19) United States
(12) Patent Application Publication
(10) Pub. No.: US 2013/0105085 A1
(43) Pub. Date: May 2, 2013

(54) PLASMA REACTOR WITH CHAMBER WALL TEMPERATURE CONTROL

(71) Applicant: Applied Materials, Inc., Santa Clara, CA (US)

(72) Inventors: IMAD YOUSIF, San Jose, CA (US); MARTIN JEFFREY SALINAS, San Jose, CA (US); SAMER BANNA, San Jose, CA (US); ANDREW NGUYEN, San Jose, CA (US); VALENTIN TODOROW, Palo Alto, CA (US); DMITRY LUBOMIRSKY, Cupertino, CA (US); ANKUR AGARWAL, Mountain View, CA (US); KALLOL BERA, San Jose, CA (US)

(73) Assignee: APPLIED MATERIALS, INC., Santa Clara, CA (US)

(21) Appl. No.: 13/647,574

(22) Filed: Oct. 9, 2012

Related U.S. Application Data
(60) Provisional application No. 61/552,806, filed on Oct. 28, 2011.
(60) Provisional application No. 61/681,370, filed on Aug. 9, 2012.

(51) Int. Cl. H01L 21/20; H01L 21/306

(52) U.S. Cl. CPC H01L 21/20; H01L 21/30604
USPC 156/345.37; 118/724; 118/723 E

(57) ABSTRACT

Apparatus for processing substrates are provided herein. In some embodiments, an apparatus includes a first conductive body disposed about a substrate support in the inner volume of a process chamber; a first conductive ring having an inner edge coupled to a first end of the second conductive body and having an outer edge disposed radially outward of the inner edge; a second conductive body coupled to the outer edge of the first conductive ring and having at least a portion disposed above the first conductive ring, wherein the first conductive ring and the at least a portion of the second conductive body partially define a first region above the first conductive ring; and a heater configured to heat the first conductive body, the second conductive body, and the first conductive ring.

### CROSS-REFERENCE TO RELATED APPLICATIONS

This application claims benefit of U.S. provisional patent application Ser. No. 61/552,806, filed Oct. 28, 2011, and U.S. provisional patent application Ser. No. 61/681,370, filed Aug. 9, 2012, each of which are herein incorporated by reference.

### FIELD

Embodiments of the present invention generally relate to substrate processing equipment.

### BACKGROUND

Substrate processing systems, such as plasma reactors, may be used to deposit, etch, or form layers on a substrate. One parameter useful for controlling aspects of such substrate processing is a wall temperature of a plasma reactor used to process a substrate.

Thus, the inventors have provided herein embodiments of substrate processing systems that may provide improved temperature control of a liner or chamber wall of the substrate processing system.

### SUMMARY

Apparatus for processing substrates are provided herein. In some embodiments, an apparatus for processing a substrate may include a first conductive body disposed about a substrate support in the inner volume of a process chamber; a first conductive ring having an inner edge coupled to a first end of the first conductive body and having an outer edge disposed radially outward of the inner edge; a second conductive body coupled to the outer edge of the first conductive ring and having at least a portion disposed above the first conductive ring, wherein the first conductive ring and the at least a portion of the second conductive body partially define a first region above the first conductive ring; and a heater configured to heat the first conductive body, the second conductive body, and the first conductive ring.

In some embodiments, a substrate processing apparatus may include a process chamber having an inner volume and a substrate support disposed in the inner volume; a first conductive body disposed about the substrate support in the inner volume of a process chamber; a first conductive ring having an inner edge coupled to a first end of the first conductive body and having an outer edge disposed radially outward of the inner edge; a second conductive body coupled to the outer edge of the first conductive ring and having at least a portion disposed above the first conductive ring, wherein the first conductive ring and the at least a portion of the second conductive body partially define a first region above the first conductive ring; and a heater configured to heat the first conductive body, the second conductive body, and the first conductive ring.

In some embodiments, a substrate processing apparatus may include a process chamber having an inner volume and a substrate support disposed in the inner volume; a first conductive body disposed about the substrate support in the inner volume of a process chamber; a first conductive ring having an inner edge coupled to a first end of the first conductive body and having an outer edge disposed radially outward of the inner edge; a second conductive body coupled to the outer edge of the first conductive ring and having at least a portion disposed above the first conductive ring, the second conductive body having a first channel disposed in the second conductive body and isolated from the inner volume, wherein the first conductive ring and the at least a portion of the second conductive body partially define a first region above the first conductive ring; a third conductive body coupled to a second end of the first conductive body opposing the first end, wherein the third conductive body, the first conductive ring, and the first conductive body partially define a second region disposed below the first region and wherein the third conductive body electrically couples and thermally decouples the first conductive body from a wall of the process chamber; a fourth body disposed externally to and about the second conductive body and having a second channel to flow a coolant through the second channel; and a heater disposed in the first channel of the second conductive body and configured to heat the first conductive body, the second conductive body, and the first conductive ring.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts schematic view of a plasma reactor in accordance with some embodiments of the present invention.

FIG. 2 depicts a schematic view of a portion the plasma reactor depicted in FIG. 1 in accordance with some embodiments of the present invention.

FIG. 3 depicts a schematic view of a chamber liner in accordance with some embodiments of the present invention.

FIGS. 4A-D respectively depict a perspective view, top view, side view, and cross sectional view of a chamber liner in accordance with some embodiments of the present invention.

FIGS. 4E-G respectively depict a side view, top view, side cross sectional view, and a partial view of a cap of the chamber liner of FIGS. 4A-D in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Apparatus for processing substrates are disclosed herein. The inventive apparatus advantageous may facilitate reduction in defect and/or particle formation on substrates during processing by controlling the temperature of the substrate processing system. Temperature control of one or more components of the substrate processing system as described herein may further improve plasma characteristics, such as plasma density and/or plasma flux, in the substrate processing system. Improved temperature control as described herein may advantageously result in improved process yield, run-to-run stability, higher throughput, or the like as discussed below.

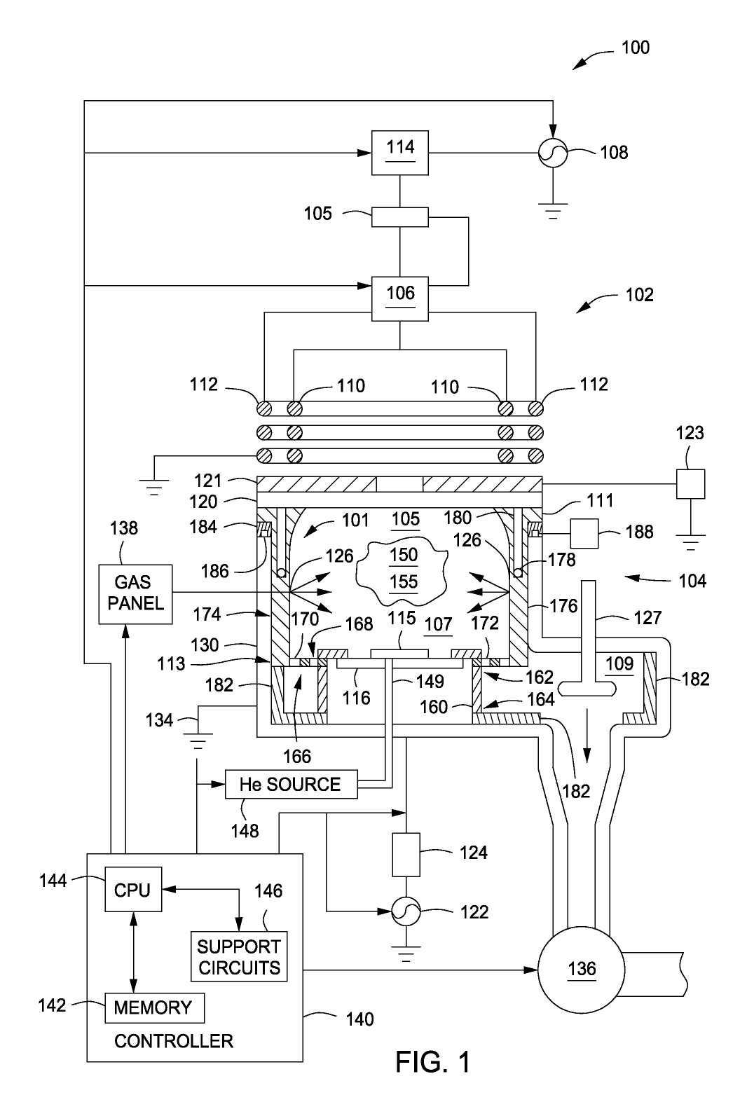

FIG. 1 depicts a schematic side view of an inductively coupled plasma reactor (reactor 100) in accordance with some embodiments of the present invention. The reactor 100 may be utilized alone or, as a processing module of an integrated semiconductor substrate processing system, or cluster tool, such as a CENTURA® integrated semiconductor wafer processing system, available from Applied Materials, Inc. of Santa Clara, Calif. Examples of suitable plasma reactors that may advantageously benefit from modification in accordance with embodiments of the present invention include inductively coupled plasma etch reactors such as the DPS® line of semiconductor equipment or other inductively coupled plasma reactors, such as MESA™ or the like also available from Applied Materials, Inc. The above listing of semiconductor equipment is illustrative only, and other etch reactors, and non-etch equipment (such as CVD reactors, or other semiconductor processing equipment) may also be suitably modified in accordance with the present teachings. For example, suitable exemplary plasma reactors that may be utilized with the inventive methods disclosed herein may be found in U.S. patent application Ser. No. 12/821,609, filed Jun. 23, 2010 by V. Todorow, et al., and entitled, “INDUCTIVELY COUPLED PLASMA APPARATUS,” or U.S. patent application Ser. No. 12/821,636, filed Jun. 23, 2010 by S. Banna, et al., and entitled, “DUAL MODE INDUCTIVELY COUPLED PLASMA REACTOR WITH ADJUSTABLE PHASE COIL ASSEMBLY.”

The reactor 100 generally includes the process chamber 104 having a conductive body (wall) 130 and a lid 120 (e.g., a ceiling) that together define an inner volume 105, a substrate support 116 having a substrate 115 disposed thereon disposed within the inner volume 105, an inductively coupled plasma apparatus 102, and a controller 140. The wall 130 is typically coupled to an electrical ground 134 and in embodiments where the reactor 100 is configured as an inductively coupled plasma reactor, the lid 120 may comprise a dielectric material facing the inner volume 105 of the reactor 100. In some embodiments, the substrate support 116 may be configured as a cathode coupled through a matching network 124 to a biasing power source 122. The biasing source 122 may illustratively be a source of up to about 1000 W (but not limited to about 1000 W) at a frequency of approximately 13.56 MHz that is capable of producing either continuous or pulsed power, although other frequencies and powers may be provided as desired for particular applications. In other embodiments, the source 122 may be a DC or pulsed DC source. In some embodiments, the source 122 may be capable of providing multiple frequencies or one or more second sources (not shown) may be coupled to the substrate support 116 through the same matching network 124 or one or more different matching networks (not shown) to provide multiple frequencies.

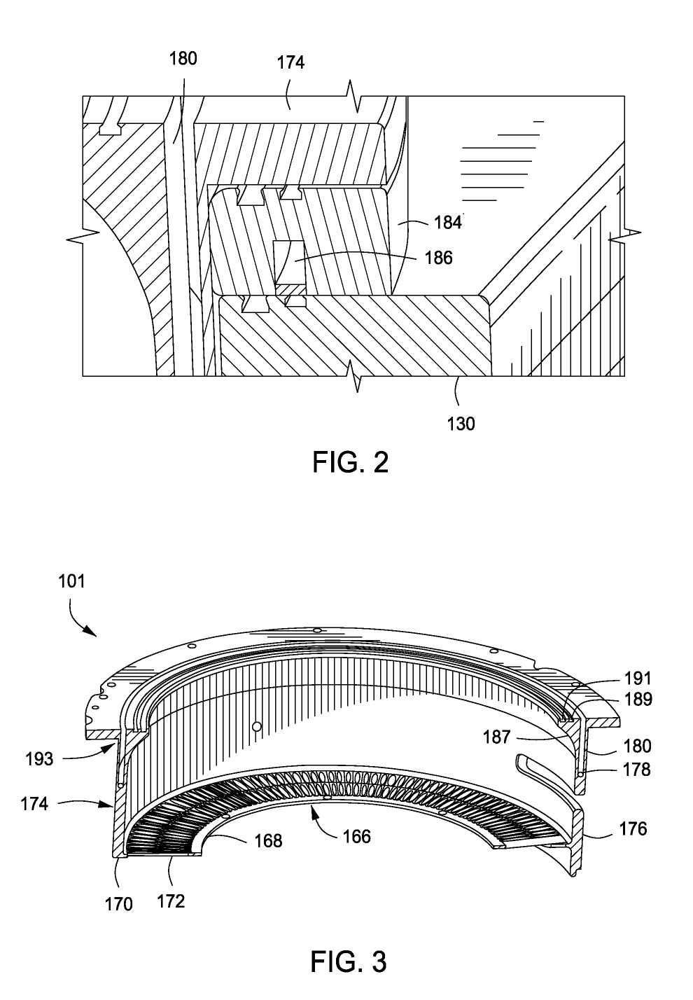

The reactor 100 may include one or more components to manage temperature and/or control plasma distribution in the reactor 100, as illustrated in FIGS. 1 through 4. For example, the one or more components may include a first conductive body 160 disposed about the substrate support 116 in the inner volume 105 of the process chamber 102. The first conductive body 160 is electrically conductive and may be a cathode sleeve (e.g., a sleeve that surrounds the substrate support 116), for example, to influence plasma behavior in the inner volume 105 and/or proximate the substrate support 116. The first conductive body 160 may have any suitable shape to provide the desired plasma behavior, for example, such as a cylinder, or the like. The first conductive body 160 may include a first end 162 and a second end 164.

In some embodiments, the reactor 100 may comprise a liner 101 disposed within the process chamber 104 to manage temperature and/or control plasma distribution in the reactor 100. The liner 101 may generally comprise a second conductive body 174 having a first channel 180 formed in a first end 111 of the second conductive body 174 and a conductive ring 166 coupled to a second end 113 of the second conductive body 174. In some embodiments, the conductive ring 166 may have an inner edge 168 coupled to the first end 162 of the first conductive body 160. Alternatively, in some embodiments, the inner edge 168 may be disposed immediately adjacent to or rest on or against the conductive body 160 at or near the first end 162. The inner edge 168 of the conductive ring 166 may be positioned with respect to the first conductive body 160 such that no gap exists between the conductive ring 166 and the first conductive body 160. An outer edge 170 of the conductive ring 166 may be disposed radially outward from the inner edge 168 of the conductive ring 166. The conductive ring 166 may be a plasma screen or the like, and may influence behavior of a plasma in the inner volume 105 of the process chamber 102 and/or proximate the substrate support 116. For example, the conductive ring 166 may include a plurality of openings 172 disposed through the conductive ring 166 to fluidly couple a first region 107 of the inner volume 105 to a second region 109 of the inner volume 105. For example, as illustrated in FIG. 1, the first region 107 may be above the substrate support 116 and the second region 109 may be adjacent to and/or below the substrate support 116. In some embodiments, the first region 107 may be a processing volume above the substrate support 116 and the second region 109 may be an exhaust volume adjacent to and/or below the substrate support 116.

The second conductive body 174 is coupled to the outer edge 170 of the conductive ring 166. At least a portion 176 of the second conductive body 174 may be disposed above the conductive ring 166 (e.g., may extend from the conductive ring 166 towards the lid 120, as illustrated in FIGS. 1 and 3. The conductive ring 166 and the at least a portion 176 of the second conductive body 174 may partially bound or define the first region 107 above the conductive ring 166. For example, the conductive ring 166, the at least a portion 176 of the second conductive body 174, and the lid 120 may together define the first region 107, as illustrated in FIG. 1. The second conductive body 174 may be a chamber liner. For example, the second conductive body 174 may be configured to line at least portions of the chamber wall 130 and may include one or more openings (not shown) such as openings to facilitate inlet of process gases in the inner volume 105 and/or inlet of the substrate 115 into the inner volume 105. For example, an opening corresponding to a slit valve opening in the chamber wall 130 is depicted in FIG. 3.

The second conductive body 174 may be utilized transfer heat from a heater 178 to inner volume facing surfaces of the second conductive body 174 as well as inner volume facing surfaces of the conductive ring 166 and the first conductive body 160. For example, the heater 178 may be configured to heat the first conductive body 160, the second conductive body 174, and the conductive ring 166. The heater 178 may be any suitable heater, such as a resistive heater or the like, and may comprise a single heating element or a plurality of heating elements. In some embodiments, the heater 178 may provide a temperature of about 100 to about 200 degrees Celsius, or about 150 degrees Celsius. The inventors have discovered that providing such temperatures facilitates a reduction of the memory effect associated with fluorine processing.

The second conductive body 174 may include a first channel 180 disposed in the second conductive body 174 and isolated from the first region 107. For example, as illustrated in FIGS. 1-3, the first channel may be disposed in an end of the at least a portion 176 of the second conductive body 174 proximate the lid 120 and may extend into the second conductive body 174. As illustrated in FIG. 1, the heater 178 may be disposed in the first channel 180. For example, the heater 178 may be a resistive heater and, in some embodiments, may be encased in a sheath, such as ICONEL®, stainless steel, or the like. In some embodiments, the heater may be located about midway in the upper liner. Locating the heater 178 not too far and not too close to the coolant channel facilitates balancing heat loss and temperature uniformity.

Referring to FIG. 3, in some embodiments, the second conductive body 174 may comprise an inwardly facing ridge 187 having a first channel 189 and a second channel 191 formed therein disposed proximate a top portion 193 of the second conductive body 174. When present, the first channel 189 and second channel 191 may be configured to allow a seal or o-ring to be disposed within one or both of the first channel 189 and second channel 191 to facilitate creating a seal between the liner 101 and other components of the reactor when installed.

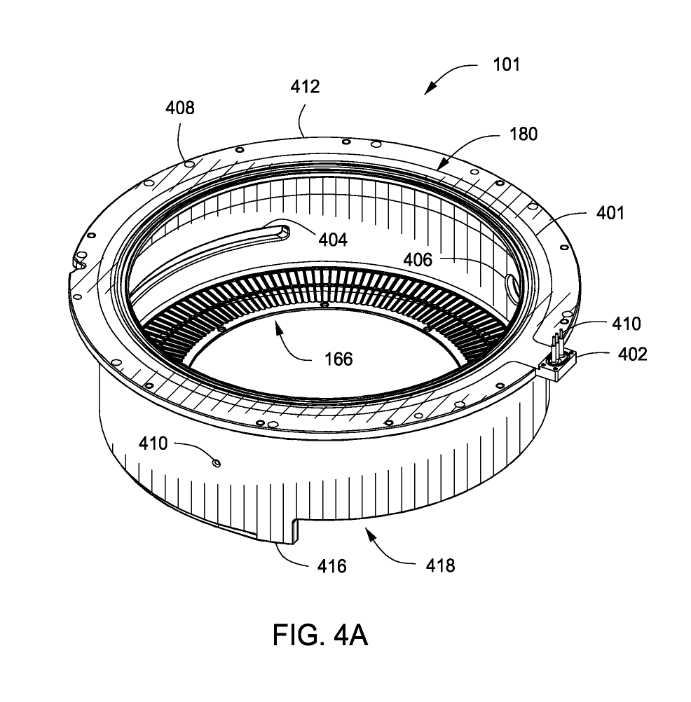

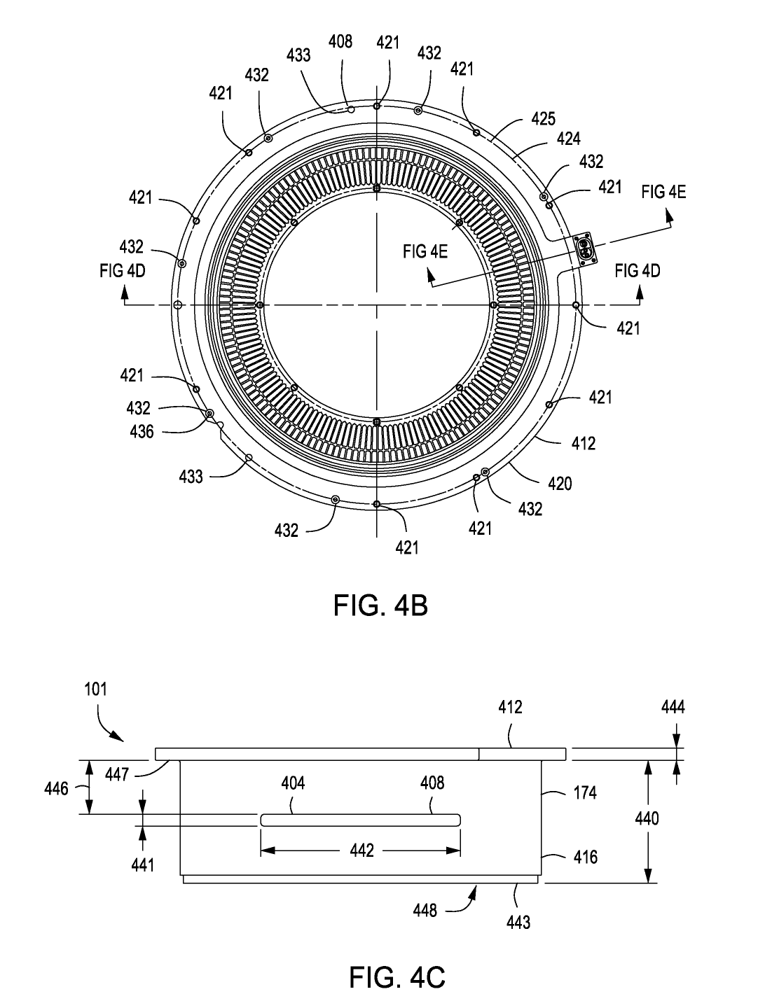

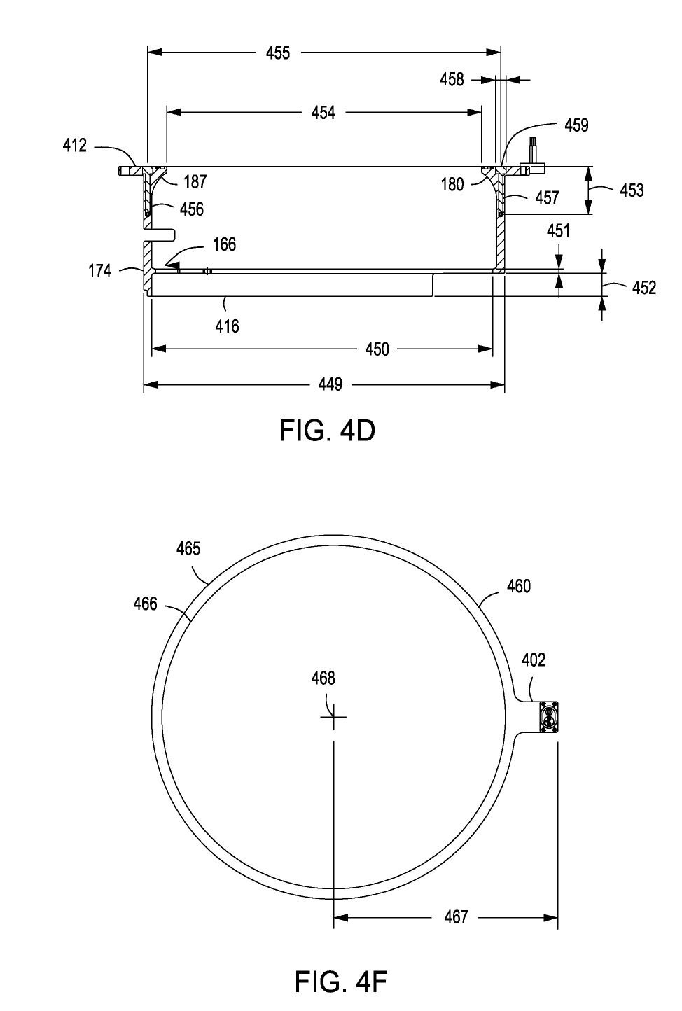

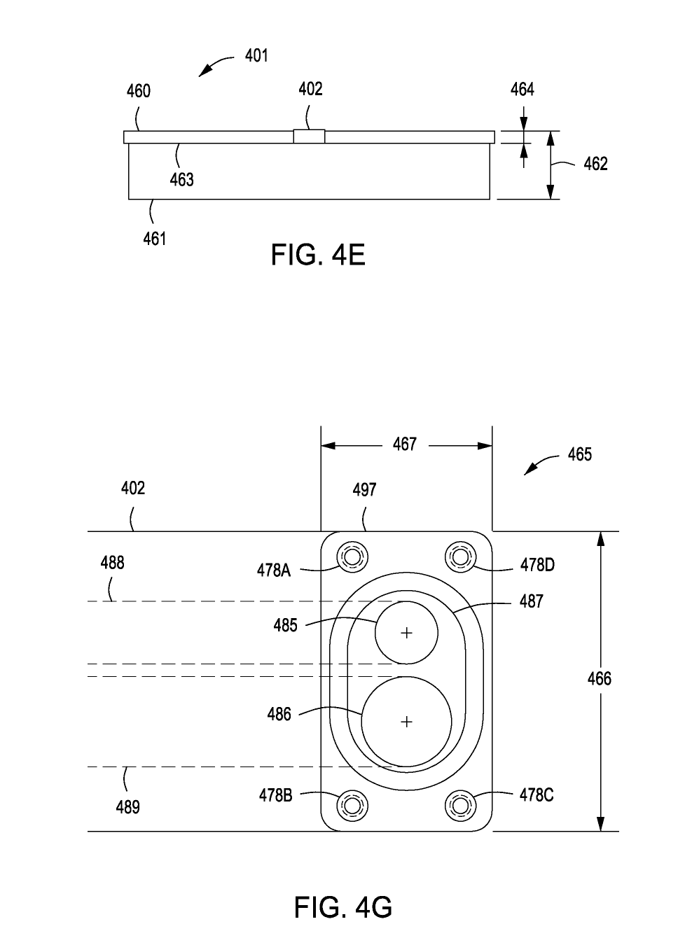

FIGS. 4A-D respectively depict a perspective view, top view, side view, and cross sectional view of the liner 101 in accordance with some embodiments of the present invention. The dimensions of the liner 101 described below advantageously allow the liner 101 to be suitable for use with a reactor, for example such as the reactor 100 described above.

Referring to 4A, in some embodiments, a cap 401 may be disposed atop the channel 180, thereby covering the channel 180. In some embodiments, the cap 401 may comprise an outwardly extending tab 402 housing one or more electrical feed-throughs 410. The electrical feed-throughs 410 facilitate the delivery of power to the heater 178 (shown in FIG. 1). In some embodiments, the liner 101 may comprise an outwardly extending flange 412 disposed at an upper end of the liner 101 and having a plurality of through holes 408 formed therein to facilitate installation of the liner 101 in the reactor.

In some embodiments, one or more openings 406, 410, 404 may be formed in the conductive body to facilitate inlet of process gases, temperature monitoring apparatus (e.g., a pyrometer, thermocouple, or the like), and/or a substrate to an area within the liner 101. In some embodiments, a bottom 418 of the liner 101 may include a downwardly extending feature 416. When present, the feature 416 may position the liner 101 when installed in the reactor such that an opening is provided between the liner 101 and an exhaust system of the process chamber, for example to couple the vacuum pump 136 to the inner volume 105 of the process chamber.

Referring to FIG. 4B, in some embodiments, the flange 412 may have a outer diameter 420 of about 25.695 inches to about 25.705 inches. The plurality of through holes 408 are arranged to interface with other components of the process chamber to facilitate installation of the liner 101 within the process chamber. In some embodiments, a first set of through holes 421 of the plurality of through holes 408 may be disposed about the flange 412 such that a common bolt circle 424 of the first set of through holes 421 has a diameter 425 of about 24.913 inches to about 24.923 inches. In some embodiments the first set of through holes 421 may have a diameter of about 0.005 to about 0.015 inches.

In some embodiments, a second set of through holes 432 of the plurality of through holes 408 may have a diameter 436 of about 0.215 inches to about 0.225 inches. In some embodiments, the second set of through holes 432 may be disposed on the common bolt circle 424. In some embodiments, a third set of through holes 433 of the plurality of through holes 408 may have a diameter of about 0.395 inches to about 0.405 inches.

In some embodiments, a plurality of through holes 434 may be formed proximate the inner edge 168 of the conductive ring 166 to facilitate installation of the liner in the process chamber. In such embodiments, the plurality of through holes 434 may disposed about the conductive ring 166 symmetrically such that an angle 437 between each through hole of the plurality of through holes 434 is about 44 degrees to about 46 degrees. In some embodiments, the plurality of through holes 434 may each have a diameter of about 0.327 inches to about 0.336 inches. In some embodiments, the conductive ring 166 may have an inner diameter 419 of about 14.115 to about 14.125 inches.

Referring to FIG. 4C, in some embodiments, the second conductive body 174 may have a height 440 of about 7.563 inches to about 7.573 inches, as measured from a bottom 443 of the feature 416 to a bottom 447 of the flange 412. In some embodiments, the flange 412 may have a thickness 444 of about 0.539 inches to about 0.549 inches. In some embodiments, a bottom of the feature 416 may have a notched portion 448 to facilitate interfacing with other components within the process chamber.

The opening 404 is configured to allow the inlet of a substrate to an area within the liner 101. In some embodiments, the opening 404 may have a thickness 441 and a width 442 suitable to facilitate ingress and egress of the substrate. In some embodiments, the opening may be formed in the second conductive body 174 such that a top 448 of the opening 404 may be a distance 446 of about 3.375 inches to about 3.385 inches from the bottom 447 of the flange 412.

Referring to FIG. 4D, in some embodiments, the second conductive body 174 may have an outer diameter 449 of about 22.595 inches to about 22.605 inches. In some embodiments, the second conductive body 174 may have an inner diameter 450 of about 21.595 inches to about 21.605 inches. In some embodiments, the ridge 187 may extend inward to an inner diameter 454 of about 19.695 inches to about 19.705 inches.

In some embodiments, the feature 416 may have a height 452 of about 1.563 inches to about 1.573 inches. In some embodiments, a thickness 451 of the conductive ring 166 may be about 0.130 inches to about 0.140 inches.

In some embodiments, the channel 180 may have a depth 453 of about 3.007 inches to about 3.017 inches. In some embodiments, the channel 180 may be formed in the second conductive body 174 such that a diameter 455 of a central axis 456 of the channel 180 may be about 22.100 inches to about 22.110 inches. In some embodiments, the channel 180 may comprise a lower portion having a thickness 458 of about 0.270 inches to about 0.280 inches. In some embodiments, the channel 180 may comprise an upper portion 459 configured to allow a top ring of the cap 401 (described below) to fit within the upper portion 459 of the channel 180.

FIGS. 4E-G respectively depict a side cross sectional view, a top view, and a partial top view of the cap 401 of the liner 101 in accordance with some embodiments of the present invention.

Referring to FIG. 4E, the cap 401 generally comprises a top ring 460 and a bottom ring 461 coupled to a bottom 463 of the top ring 460. In some embodiments, the cap 401 may have an overall height 462 of about 2.940 inches to about 2.950 inches. The bottom ring 461 is configured to fit within the bottom portion 457 of the channel 180 (described above). In some embodiments, the top ring 460 has a thickness 464 of about 0.42 inches to about 0.44 inches. For example, in some embodiments, the bottom ring 416 of the cap has an outer diameter 462 of about 22.365 inches to about 22.375 inches. In some embodiments, the bottom ring 416 has an inner diameter 463 of about 21.835 inches to about 21.845 inches.

Referring to FIG. 4F, the top ring 460 is configured to fit within the upper portion 459 of the channel 459 (described above). In some embodiments, the top ring 460 may comprise an outer diameter 465 of about 22.795 inches to about 22.805 inches. In some embodiments, the top ring 460 may comprise an inner diameter 466 of about 21.495 inches to about 21.505 inches. In some embodiments, the outwardly extending tab 402 may extend to a distance 467 of about 14.03 inches to about 14.05 inches from a center 468 of the cap 401.

Referring to FIG. 4G, in some embodiments, the outwardly extending tab 402 comprises a plate 497 coupled to the tab 402 proximate an end 465 of the tab 402. When present, the plate 497 secures one or more electrical feedthroughs (electrical feedthroughs 410 shown in FIG. 4B) to facilitate providing power to the heater (heater 178 shown in FIG. 3).

In some embodiments, the plate 497 may have a length 466 of about 1.99 inches to about 2.01 inches. In some embodiments, the plate 497 may have a width 467 of about 0.545 inches to about 0.555 inches. In some embodiments, four through holes 478A-D may be formed through the plate 497 to facilitate coupling the plate to the tab 402. In some embodiments, each of the four through holes 478A-D may be formed proximate a respective corner of the plate 497.

A first feedthrough hole 485 and second feedthrough hole 486 may be formed in an inner portion 487 of the plate 497 and coupled to a respective first conduit 488 and second conduit 489 formed in the tab 402. Each of the first conduit 488 and second conduit 489 facilitates a path from the first feed through hole 485 and second feed through hole 486 to the heater (heater 178 shown in FIG. 3) to facilitate providing power to the heater.

Referring back to FIG. 1, a third conductive body 182 may be disposed adjacent to the second end 164 of the first conductive body 160 opposite the first end 162. In some embodiments, the third conductive body 182 may be coupled to the second end 164 of the first conductive body 160 opposite the first end 162. The third conductive body 182, the conductive ring 166, and the first conductive body 160 may bound, or partially define, the second region 109 disposed below the first region 107 of the inner volume 105. The inventors have discovered that controlling temperature of inner volume facing surfaces of the one or more components 160, 166, 174, and/or 182 can be utilized to reduce defect and/or particle formation on the substrate 115. For example, the inventors have discovered that if the temperature of the inner volume facing surfaces of the one or more components is not controlled, then various species, such as process gases, plasma species and/or byproducts formed from interaction with the substrate 115 may form on the inner volume facing surfaces. During processing the various species may flake off the inner volume facing surfaces and contaminate the substrate 115. In some embodiments, such as when fluorine (F) containing gases are used, the chamber 102 may require a separate plasma cleaning to remove fluorine-containing species formed on the inner volume facing surfaces. However, improved control of temperature of the inner volume facing surfaces of the one or more components 160, 166, 174, and/or 182 during processing time and/or idle time between substrates may reduce the need for such cleanings and may extend the mean time between cleanings for the reactor 100. Further, temperature variation along the inner volume facing surfaces of the one or more components 160, 166, 174 and/or 182 may result in non-uniformities in a plasma formed in the process chamber 102. As such, embodiments of the present invention may facilitate more uniform temperature along the inner volume facing surfaces of the one or more components 160, 166, 174 and/or 182 that may result in a more uniform plasma formed in the process chamber 102 as compared to conventional processing chambers. In addition, the present invention provides a more uniform RF ground path within the chamber, thereby facilitating plasma uniformity.

In some embodiments, the third conductive body 182 may facilitate control over temperature on the inner volume facing surfaces of the one or more components 160, 166, 174, and/or 182. For example, the inventors have discovered that when the second end 164 of the first conductive body 160 is directly coupled to the chamber wall 130, for example, at the base of the chamber 102, that temperature of the inner volume facing surfaces may be difficult to control due to rapid heat loss to the chamber wall 130. For example, the chamber wall 130 may act as a heat sink which may result in temperature variation on the inner volume facing surfaces of the one or more components 160, 166, and/or 174. Accordingly, the inventors have provided the third conductive body 182 to improve temperature control on the inner volume facing surfaces. For example, the third conductive body 182 may prevent the first conductive body 160 from directly contacting the wall 130 of the process chamber. Accordingly, the third conductive body 182 may prevent heat loss due to transfer to the chamber wall 130, and instead may facilitate more uniform temperature distribution about the inner volume facing surfaces of the one or more components 160, 166, 174, and/or 182. The conductive bodies and conductive rings described herein may be fabricated from any suitable process compatible materials, such as aluminum (e.g., T6 6061) or the like. In some embodiments, the materials may be treated and/or coated, such as by anodization or having a coating of yttrium deposited thereon.

Further, the first conductive body 160 may remain electrically coupled to the chamber wall 130 of the process chamber 102 via the third conductive body 182. However, through the presence of the third conductive body 182, the first conductive body 160 may be thermally decoupled from the wall 130 of the process chamber 102.

Temperature control may further be provided by a fourth body 184 disposed externally to and about the second conductive body 174. For example, as illustrated in FIG. 1, the fourth body 184 may be disposed above the chamber wall 130 and below at least a portion of the second conductive body 174 proximate the lid 120. In some embodiments, the fourth body 184 may be a ring or a spacer disposed between a flange of the second conductive body 174 and the chamber wall 130. For example, as illustrated the fourth body 184 may be disposed about the second conductive body 174 proximate the location of the first channel 180 and the heater 178. Alternatively, the fourth body 184 may be located at any suitable location about the second conductive body 174 to improve temperature control of the one or more components 160, 166, 174 and/or 182.

The fourth body 184 may include a second channel 186 to flow a coolant through the second channel 186. For example, the coolant may act in combination with the heater 178 to provide the desired temperature to the inner surfaces of the one or more components 160, 166, 174, and/or 182. The coolant may include any suitable coolant such as one or more of ethylene glycol, water, or the like. The coolant may be provided to the second channel 186 by a coolant source 188. The coolant may be provided at a temperature of about 65 degrees Celsius, or other suitable temperature depending upon the process being performed. For example, the heater 178 and the coolant may act in combination to provide temperatures of about 100 to about 200, or about 150 degrees Celsius to the inner surfaces of the one or more components 160, 166, 174 and/or 182.

The one or more components 160, 166, 174 and/or 182 may include additional features to improve temperature control, plasma uniformity, and/or process yield in the process chamber 102. For example, the openings of the second conductive body 174, such as to facilitate inlet of a process gas and/or a substrate may be anodized. For example, the composition of the first conductive body 160, the second conductive body 174, the third conductive body 182 and/or the conductive ring 166 may be selected to improve heat transfer. For example, in some embodiments, the first conductive body 160, the second conductive body 174, the third conductive body 182 and/or the conductive ring 166 may comprise aluminum (Al), and in some embodiments, anodized aluminum, or the like. For example, one or more of the components 160, 166, 174, and/or 182 may be fabricated in a single piece to improve heat transfer. For example, in some embodiments, the second conductive body 174 and the conductive ring 166 may be fabricated in a single piece. Alternatively, one or more of the components 160, 166, 174, and/or 182 may be fabricated from separate pieces and coupled together using a suitable fastener to provide a robust connection with good thermal contact, such as one or more of bolts, clamps, springs, or the like. In some embodiments, a coating may be formed on the inner volume facing surfaces of the one or more components 160, 166, 174, and/or 182 to limit corrosion and/or sticking that may otherwise facilitate particulate deposition on and/or defects formed in the substrate 115. For example, in some embodiments, a non-conductive coating may be formed on surfaces (e.g., inner volume facing surfaces) of the second conductive body 174 and the conductive ring 166. In some embodiments, the non-conductive coating may comprise one or more of yttrium oxide (Y₂O₃), or the like.

Returning to FIG. 1, in some embodiments, the lid 120 may be substantially flat. Other modifications of the chamber 104 may have other types of lids such as, for example, a dome-shaped lid or other shapes. The inductively coupled plasma apparatus 102 is typically disposed above the lid 120 and is configured to inductively couple RF power into the process chamber 104. The inductively coupled plasma apparatus 102 includes the first and second coils 110, 112, disposed above the lid 120. The relative position, ratio of diameters of each coil, and/or the number of turns in each coil can each be adjusted as desired to control, for example, the profile or density of the plasma being formed via controlling the inductance on each coil. Each of the first and second coils 110, 112 is coupled through a matching network 114 via the RF feed structure 106, to the RF power supply 108. The RF power supply 108 may illustratively be capable of producing up to about 4000 W (but not limited to about 4000 W) at a tunable frequency in a range from 50 kHz to 13.56 MHz, although other frequencies and powers may be provided as desired for particular applications.

In some embodiments, a power divider 105, such as a dividing capacitor, may be provided between the RF feed structure 106 and the RF power supply 108 to control the relative quantity of RF power provided to the respective first and second coils. For example, as shown in FIG. 1, the power divider 105 may be disposed in the line coupling the RF feed structure 106 to the RF power supply 108 for controlling the amount of RF power provided to each coil (thereby facilitating control of plasma characteristics in zones corresponding to the first and second coils). In some embodiments, the power divider 105 may be incorporated into the match network 114. In some embodiments, after the power divider 105, RF current flows to the RF feed structure 106 where it is distributed to the first and second RF coils 110, 112. Alternatively, the split RF current may be fed directly to each of the respective first and second RF coils.

A heater element 121 may be disposed atop the lid 120 to facilitate heating the interior of the process chamber 104. The heater element 121 may be disposed between the lid 120 and the first and second coils 110, 112. In some embodiments. the heater element 121 may include a resistive heating element and may be coupled to a power supply 123, such as an AC power supply, configured to provide sufficient energy to control the temperature of the heater element 121 to be between about 50 to about 100 degrees Celsius. In some embodiments, the heater element 121 may be an open break heater. In some embodiments, the heater element 121 may comprise a no break heater, such as an annular element, thereby facilitating uniform plasma formation within the process chamber 104.

During operation, the substrate 115 (such as a semiconductor wafer or other substrate suitable for plasma processing) may be placed on the substrate support 116 and process gases may be supplied from a gas panel 138 through entry ports 126 to form a gaseous mixture 150 within the process chamber 104. For example, prior to introduction of the process gases, the one or more components 160, 166, 174, and/or 182 may be controlled, for example, by the heater 178 and the coolant as discussed above to have inner volume facing surfaces at a temperature of between about 100 to 200 degrees Celsius, or about 150 degrees Celsius. The gaseous mixture 150 may be ignited into a plasma 155 in the process chamber 104 by applying power from the plasma source 108 to the first and second coils 110, 112. In some embodiments, power from the bias source 122 may be also provided to the substrate support 116. The pressure within the interior of the chamber 104 may be controlled using a throttle valve 127 and a vacuum pump 136. The temperature of the chamber wall 130 may be controlled using liquid-containing conduits (not shown) that run through the wall 130.

The temperature of the substrate 115 may be controlled by stabilizing a temperature of the substrate support 116. In some embodiments, helium gas from a gas source 148 may be provided via a gas conduit 149 to channels defined between the backside of the substrate 115 and grooves (not shown) disposed in the substrate support surface. The helium gas is used to facilitate heat transfer between the substrate support 116 and the substrate 115. During processing, the substrate support 116 may be heated by a resistive heater (not shown) within the substrate support to a steady state temperature and the helium gas may facilitate uniform heating of the substrate 115. Using such thermal control, the substrate 115 may illustratively be maintained at a temperature of between 0 and 500 degrees Celsius.

The controller 140 comprises a central processing unit (CPU) 144, a memory 142, and support circuits 146 for the CPU 144 and facilitates control of the components of the reactor 100 and, as such, of methods of forming a plasma, such as discussed herein. The controller 140 may be one of any form of general-purpose computer processor that can be used in an industrial setting for controlling various chambers and sub-processors. The memory, or computer-readable medium, 142 of the CPU 144 may be one or more of readily available memory such as random access memory (RAM), read only memory (ROM), floppy disk, hard disk, or any other form of digital storage, local or remote. The support circuits 146 are coupled to the CPU 144 for supporting the processor in a conventional manner. These circuits include cache, power supplies, clock circuits, input/output circuitry and subsystems, and the like. The memory 142 stores software (source or object code) that may be executed or invoked to control the operation of the reactor 100 in the manner described herein. The software routine may also be stored and/or executed by a second CPU (not shown) that is remotely located from the hardware being controlled by the CPU 144.

While the foregoing is directed to embodiments of the present invention, other and further embodiments of the invention may be devised without departing from the basic scope thereof.

1. An apparatus, comprising:
a first conductive body disposed about a substrate support in the inner volume of a process chamber;
a first conductive ring having an inner edge coupled to a first end of the first conductive body and having an outer edge disposed radially outward of the inner edge;
a second conductive body coupled to the outer edge of the first conductive ring and having at least a portion disposed above the first conductive ring, wherein the first conductive ring and the at least a portion of the second conductive body partially define a first region above the first conductive ring; and
a heater configured to heat the first conductive body, the second conductive body, and the first conductive ring.

2. The apparatus of claim 1, further comprising:
a third conductive body coupled to a second end of the first conductive body opposing the first end, wherein the third conductive body, the first conductive ring, and the first conductive body partially define a second region disposed below the first region.

3. The apparatus of claim 2, wherein the first conductive ring further comprises:
a plurality of openings disposed through the first conductive ring to fluidly couple the first region above the processing surface of the substrate support to the second region.

4. The apparatus of claim 1, wherein the second conductive body further comprises:
a first channel isolated from the first region, wherein the first channel is disposed in the second conductive body and about the first region and wherein the heater is disposed in the first channel.

5. The apparatus of claim 1, wherein the first conductive body, the second conductive body, the third conductive body and the first conductive ring comprise aluminum (Al).

6. The apparatus of claim 1, further comprising:
a non-conductive coating formed on surfaces of the second conductive body and the first conductive ring that face the first region.

7. The apparatus of claim 1, further comprising:
a fourth body disposed externally to and about the second conductive body and having a second channel to flow a coolant through the second channel.

8. The apparatus of claim 1, wherein the second conductive body and the first conductive ring are fabricated in a single piece.

9. A substrate processing apparatus, comprising:
a process chamber having an inner volume and a substrate support disposed in the inner volume;
a first conductive body disposed about the substrate support in the inner volume of a process chamber;
a first conductive ring having an inner edge coupled to a first end of the first conductive body and having an outer edge disposed radially outward of the inner edge;
a second conductive body coupled to the outer edge of the first conductive ring and having at least a portion disposed above the first conductive ring, wherein the first conductive ring and the at least a portion of the second conductive body partially define a first region above the first conductive ring; and
a heater configured to heat the first conductive body, the second conductive body, and the first conductive ring.

10. The substrate processing apparatus of claim 9, further comprising:
a third conductive body coupled to a second end of the first conductive body opposing the first end, wherein the third conductive body, the first conductive ring, and the first conductive body partially define a second region disposed below the first region.

11. The substrate processing apparatus of claim 10, wherein the third conductive body prevents the first conductive body from contacting a wall of the process chamber.

12. The substrate processing apparatus of claim 11, wherein the first conductive body is electrically coupled to the wall of the process chamber via the third conductive body and thermally decoupled from the wall of the process chamber via the third conductive body.

13. The substrate processing apparatus of claim 10, wherein the first conductive ring further comprises:
a plurality of openings disposed through the first conductive ring to fluidly couple the first region above the processing surface of the substrate support to the second region.

14. The substrate processing apparatus of claim 9, wherein the second conductive body further comprises:
a first channel isolated from the first region, wherein the first channel is disposed in the second conductive body and about the first region and wherein the heater is disposed in the first channel.

15. The substrate processing apparatus of claim 9, further comprising:
a fourth body disposed externally to and about the second conductive body and having a second channel to flow a coolant through the second channel.

16. The substrate processing apparatus of claim 15, further comprising:
a coolant source to provide a coolant to the second channel of the fourth conductive body.

17. The substrate processing apparatus of claim 9, further comprising:
an inductively coupled plasma apparatus disposed above a ceiling of the process chamber, the inductively coupled plasma apparatus having a first RF coil and a second RF coil coupled to a RF power supply.

18. A substrate processing apparatus, comprising:
a process chamber having an inner volume and a substrate support disposed in the inner volume;
a first conductive body disposed about the substrate support in the inner volume of a process chamber;
a first conductive ring having an inner edge coupled to a first end of the first conductive body and having an outer edge disposed radially outward of the inner edge;
a second conductive body coupled to the outer edge of the first conductive ring and having at least a portion disposed above the first conductive ring, the second conductive body having a first channel disposed in the second conductive body and isolated from the inner volume, wherein the first conductive ring and the at least a portion of the second conductive body partially define a first region above the first conductive ring;
a third conductive body coupled to a second end of the first conductive body opposing the first end, wherein the third conductive body, the first conductive ring, and the first conductive body partially define a second region disposed below the first region and wherein the third conductive body electrically couples and thermally decouples the first conductive body from a wall of the process chamber;
a fourth body disposed externally to and about the second conductive body and having a second channel to flow a coolant through the second channel; and
a heater disposed in the first channel of the second conductive body and configured to heat the first conductive body, the second conductive body, and the first conductive ring.

19. The substrate processing apparatus of claim 18, wherein the first conductive ring further comprises:
a plurality of openings disposed through the first conductive ring to fluidly couple the first region above the processing surface of the substrate support to the second region.

20. The substrate processing apparatus of claim 19, further comprising:
an inductively coupled plasma apparatus disposed above a ceiling of the process chamber, the inductively coupled plasma apparatus having a first RF coil and a second RF coil coupled to a RF power supply.
